(19) United States
(12) Patent Application Publication
(10) Pub. No.: US 2023/0162969 A1
(43) Pub. Date: May 25, 2023

(54) METHOD FOR GRINDING SEMICONDUCTOR WAFERS

(71) Applicant: Siltronic AG, Munich (DE)

(72) Inventors: Michael Kerstan, Burghausen (DE); Stephan Oberhans, Obing (DE); Robert Weiss, Winhoering (DE)

(21) Appl. No.: 17/919,540

(22) PCT Filed: Apr. 12, 2021
(86) PCT No.: PCT/EP2021/059415

§ 371 Date: Oct. 18, 2022

(30) Foreign Application Priority Data
Apr. 23, 2020 (EP) 20170996.1

(51) Int. Cl. H01L 21/02; B24B 37/04

(52) U.S. Cl. CPC H01L 21/02013; B24B 37/042

(57) ABSTRACT

A method grinds a semiconductor wafer by treating the semiconductor wafer so as to remove material by way of a grinding tool containing grinding teeth having a height h, with a coolant being supplied into a contact region between the semiconductor wafer and the grinding tool, in which, at any time of the grinding, a flushing fluid is applied onto a region on one side of the semiconductor wafer by way of a nozzle.

### CROSS-REFERENCE TO PRIOR APPLICATIONS

This application is a U.S. National Phase application under 35 U.S.C. § 371 of International Application No. PCT/EP2021/059415, filed on Apr. 12, 2021, and claims benefit to European Patent Application No. EP 20170996.1, filed on Apr. 23, 2020. The International Application was published in German on Oct. 28, 2021 as WO 2021/213827 A1 under PCT Article 21(2).

### FIELD

The present disclosure is related to a method for grinding a wafer made from semiconductor material.

### BACKGROUND

The electronics, microelectronics, and microelectromechanics sectors require semiconductor wafers (substrates) that have extreme requirements in terms of global and local planarity, one-sided local planarity (nanotopology), roughness and cleanness as starting materials. Semiconductor wafers are wafers made from semiconductor materials, in particular compound semiconductors such as gallium arsenide or elemental semiconductors such as silicon and germanium.

Semiconductor wafers are produced in a multiplicity of successive process steps. The following production sequence is generally used:
producing a single-crystal semiconductor rod (crystal growth);
splitting the semiconductor rod into individual rod pieces,
dividing the rod into individual wafers (inner diameter or wire sawing),
mechanically treating the wafers (lapping, grinding),
chemically treating the wafers (alkaline or acidic etching),
chemically and mechanically treating the wafers (polishing),
optional further coating steps (for example epitaxy, temperature treatment)

The mechanical treatment of the semiconductor wafer serves to remove corrugations caused by sawing, to remove the surface layers damaged in terms of crystalline structure by the rougher sawing processes or contaminated by the sawing wire, and primarily to globally planarize the semiconductor wafers. The mechanical treatment of the semiconductor wafer furthermore serves to produce a uniform thickness distribution, that is to say that the wafer has a uniform thickness.

Lapping and surface grinding (single-disk, double-disk) are known as methods for mechanically treating the semiconductor wafers.

The double-disk lapping technique for several semiconductor wafers at the same time has been known for some time and is described for example in EP 547894 A1. In double-disk lapping, the semiconductor wafers are moved under a certain pressure, with the supply of a suspension containing an abrasive substance between an upper and a lower working disk, the lapping disk, which usually consists of steel and is provided with channels for the improved distribution of the suspension, thereby removing material. The semiconductor wafer is guided by a carrier having cutouts for receiving the semiconductor wafers during the lapping, wherein the semiconductor wafer is kept on a geometrical path by the carrier, which is set in rotation by way of an inner and outer drive sprocket.

In single-disk grinding, the semiconductor wafer is held on the rear side on a chuck and planarized on the front side by a cup grinding wheel, with the chuck and grinding wheel rotating and a slow axial and radial infeed. Methods and devices for the single-disk surface grinding of a semiconductor wafer are known, for example, from US 2008 021 40 94 A1 or from EP 0 955 126 A2.

In simultaneous double-disk grinding (sDDG), the semiconductor wafer is treated on both sides at the same time in a manner floating freely between two grinding disks mounted on opposing collinear spindles and in the process guided axially between a water cushion (hydrostatic principle) or air cushion (aerostatic principle) acting on the front and rear side largely freely from constraint forces and kept from floating away radially by a thin, loosely surrounding guide ring or by individual radial spokes. Methods and devices for the simultaneous double-disk surface grinding of a semiconductor wafer are known for example from EP 0 755 751 A1, EP 0 971 398 A1, DE 10 2004 011 996 A1 and DE 10 2006 032 455 A1.

However, double-disk grinding (DDG) of semiconductor wafers, owing to kinematics, in principle causes a higher removal of material in the center of the semiconductor wafer (“grinding navel”). In order, after grinding, to obtain a semiconductor wafer with as good as possible geometry, the two grinding spindles on which the grinding disks are mounted should be aligned exactly collinearly, since radial and/or axial deviations have a negative influence on the shape and nanotopology of the ground wafer. German application DE 10 2007 049 810 A1 teaches for example a method for correcting the grinding spindle position in double-disk grinding machines.

In grinding processes—this relates both to single-disk and to double-disk grinding methods—the grinding tool and/or the treated semiconductor wafer should be cooled. Water or deionized water is usually used as coolant. In double-disk grinding machines, the coolant usually leaves the center of the grinding tool and is transported or catapulted by way of centrifugal force to the grinding teeth that are arranged in a circular shape on the outer edge of the grinding disk. The coolant throughput, that is to say the amount of coolant that leaves within a defined time, may be controlled electronically or mechanically.

DE 10 2007 030 958 A1 teaches a method for grinding semiconductor wafers in which the semiconductor wafers are treated so as to remove material on one side or both sides by way of at least one grinding tool, with a coolant being supplied. In order to ensure constant cooling during the grinding, the coolant flow is reduced as the grinding tooth height decreases, since a coolant flow kept high without being changed would otherwise inevitably lead to aquaplaning effects.

The disclosure in DE 10 2017 215 705 A1 is based on the optimum distribution of a fluid in a grinding tool for treating a semiconductor wafer so as to remove material on both sides at the same time, this being achieved using an optimized skidding plate. It is taught here that an uneven distribution of the fluid has a negative effect on the grinding result.

US 2019/134782 A1 discloses certain designs of grinding disks that may be used for double-disk grinding. It is also taught to use water that is applied onto the semiconductor wafer by way of a nozzle.

All of the above-mentioned documents have the common disadvantage that the removal of material is higher in the center of the semiconductor wafers than at the edge. This thereby worsens the geometric parameters of the semiconductor wafer in this treatment step. This deviation is not, or not sufficiently, corrected in the following treatment steps.

### SUMMARY

In an embodiment, the present disclosure provides a method that grinds a semiconductor wafer by treating the semiconductor wafer so as to remove material by way of a grinding tool containing grinding teeth having a height h, with a coolant being supplied into a contact region between the semiconductor wafer and the grinding tool, in which, at any time of the grinding, a flushing fluid is applied onto a region on one side of the semiconductor wafer by way of a nozzle.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows the result of two series of tests with regard to the geometry in the center of semiconductor wafers. The ordinate in this case shows the deviation in the geometry (G) from an ideal geometry in the center region of the semiconductor wafers.

### DETAILED DESCRIPTION

Aspects of the present disclosure provide a method that does not exhibit the abovementioned disadvantages associated with the state of the art.

The present disclosure provides a method for grinding a wafer made from semiconductor material. Aspects of the present disclosure are based on providing an optimum distribution of a fluid in the surroundings of the grinding tool in order to treat a semiconductor wafer so as to remove material from both sides at the same time.

In an exemplary embodiment of the present disclosure, a method is provided for grinding a semiconductor wafer, in which the semiconductor wafer is treated so as to remove material by way of a grinding tool containing grinding teeth having a height h, with a coolant being supplied into a contact region between semiconductor wafer and the grinding tool, wherein, at any time of the grinding, a flushing fluid is applied onto a region on one side of the semiconductor wafer by way of a nozzle.

It has proven to be particularly advantageous when both sides of the semiconductor wafer are treated so as to remove material and a flushing fluid is applied onto a region on both sides of the semiconductor wafer.

It is particularly preferable in this case for the amount of coolant per time to be reduced as the height h of the grinding teeth of the grinding tool decreases.

It is advantageous for the sum of the amount of coolant per time and the amount of flushing fluid per time to remain constant during the grinding.

The excess pressure of the flushing fluid measured at the nozzle that is used is preferably not less than 0.1 bar and particularly preferably not more than 0.5 bar.

It should preferably be ensured that the amount of flushing fluid per time is not less than 0.1 l/min and not more than 1 l/min.

Particular attention should be paid to the region on the semiconductor wafer onto which the flow of flushing fluid is directed during the grinding. In this case, a region at a distance of not less than 2 mm, preferably 4 mm and not greater than 10 mm, preferably not greater than 6 mm from the center of the semiconductor wafer is preferred.

The nozzle that is used in this case preferably has a surface area not greater than 1.5 mm², and not less than 0.1 mm².

It is particularly preferable for the amount of flushing fluid per time to remain constant during the entire grinding process.

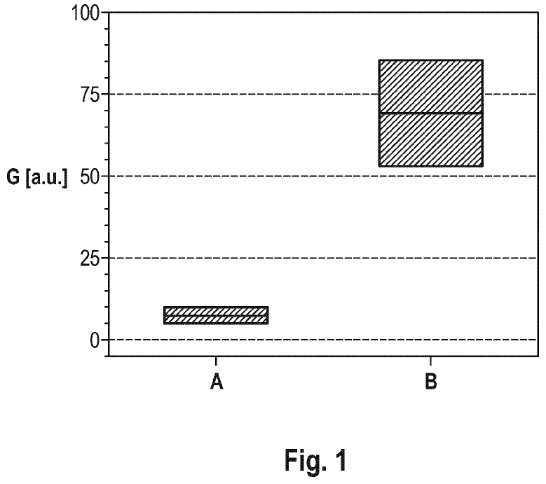

FIG. 1 shows the result of two series of tests with regard to the geometry in the center of semiconductor wafers. The ordinate in this case shows the deviation in the geometry (G) from an ideal geometry in the center region of the semiconductor wafers.

The semiconductor wafers in group B (prior art) in this case on average exhibit a greater deviation from the desired geometry than the semiconductor wafers in group A (according to the present disclosure). It is also the case that the statistical distribution of the measured deviations for the method according to the present disclosure (group A) causes a narrower distribution than in the case of the semiconductor wafers that were processed in accordance with the prior art (group B).

A piece of crystal having a nominal diameter of 300 mm made from silicon, obtained from a crystal rod that was pulled using the Czochralski method, was cut into semiconductor wafers by way of a wire saw. The semiconductor wafers thus obtained were divided into two groups “A” and “B”, wherein each second semiconductor wafer was assigned to group A and the rest of the semiconductor wafers were assigned to group “B”.

The semiconductor wafers in both groups A and B were ground on a Koyo DSGX320 grinding system. The grinding system was in this case equipped with a commercially available grinding wheel of the type #3000-OVH from the company ALMT.

The semiconductor wafers in group B were in this case ground in accordance with the prior art.

According to the prior art, the amount of grinding water is supplied to the process in a manner controlled depending on tooth height (in accordance with DE 10 2007 030 958 A1). It is thereby ensured that there is no floating, equivalent to aquaplaning, of the tool on the wafer to be treated when an excessive amount of grinding water is pressed out on the path from the inside of the tool during the process, and there is no overheating, equivalent to grinding burn, of the wafer to be treated and failure of the grinding wheel when there is too little grinding water available in the process.

The semiconductor wafers in group A were by contrast ground using a method in which a flushing fluid is added during the grinding process in addition to the coolant that is used during the grinding in order to cool the semiconductor wafer. It was ensured here that the flushing fluid has a noteworthy flow at any time.

A noteworthy flow should be understood in this case to be a flow of 0.01 l/min.

Water was preferably used for the flushing fluid, but it is also conceivable for additional additives to be used.

Adding a flushing medium in this way resulted in the geometry in the center of the wafer being considerably improved. If however the flow of flushing medium is interrupted during the grinding process, this also worsens the geometry of the semiconductor wafer in the center again.

It is in accordance with the present disclosure for the flushing medium to be directed substantially onto a region around the center of the semiconductor wafer. It is in accordance with the present disclosure, during the grinding, for the region to be at a distance of not less than 2 mm, preferably 4 mm and not greater than 10 mm, preferably not greater than 6 mm from the center of the semiconductor wafer.

The effect appears to be particularly good when the flow of the flushing medium is more than 0.1 l/min and not more than 1 l/min.

The inventors have identified that using a nozzle having a minimum nozzle cross section between 0.1 mm² and 1.5 mm² has a particularly advantageous impact on the effect.

The inventors have furthermore identified that the pressure that is set obviously also plays a role in the improvement. An excess pressure set at the nozzle of between 0.1 bar and 0.5 bar thus has a particularly positive effect.

Both groups of semiconductor wafers “A” and “B” were measured in terms of the geometry achieved after grinding. In this case, the respective deviation in the measured geometry in the center of the semiconductor wafer was compared with an ideal geometry, and the difference was given as a measured value.

FIG. 1 shows the comparison of the semiconductor wafers in group A (according to the present disclosure) and the semiconductor wafers in group B (prior art).

The semiconductor wafers in group B (prior art) in this case on average have a greater deviation from the desired geometry than the semiconductor wafers in group A (according to the present disclosure). The method according to the present disclosure thus improves the geometry in the center of the semiconductor wafers in comparison with the method according to the prior art.

It is additionally the case that the statistical distribution of the measured deviations for the method according to the present disclosure (group A) causes a narrower distribution than in the case of the semiconductor wafers that were processed in accordance with the prior art (group B). This means that the method according to the present disclosure furthermore also offers additional advantages regarding to the statistical distribution of the geometry values in the center of the semiconductor wafers.

The inventors were surprised by the fact that a comparatively small amount of flushing fluid that is not applied into the direct active region of the grinding wheel achieves a large effect in terms of improving the geometry.

It has been possible up until now to speculate about the corresponding relationships and causes, and they are not clear to the inventors.

The above description of illustrative embodiments is to be understood as being exemplary. The disclosure made thereby enables a person skilled in the art, on the one hand, to understand the present invention and the advantages associated therewith and also comprises, on the other hand, alterations and modifications to the described structures and methods that are obvious within the understanding of a person skilled in the art. All such alterations and modifications and also equivalents shall therefore be covered by the scope of protection of the claims.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A method for grinding a semiconductor wafer, the method comprising:
treating the semiconductor wafer so as to remove material by way of a grinding tool containing grinding teeth having a height h, with a coolant being supplied into a contact region between the semiconductor wafer and the grinding tool, in which, at any time of the grinding, a flushing fluid is applied onto a region on one side of the semiconductor wafer by way of a nozzle.

2. The method as claimed in claim 1, wherein two sides of the semiconductor wafer are treated at the same time so as to remove the material and the flushing fluid is applied onto a respective region on both of the two sides of the semiconductor wafer.

3. The method as claimed in claim 1, wherein an amount of coolant supplied per time is reduced as the height h decreases.

4. The method as claimed in claim 1, wherein a sum of an amount of coolant supplied per time and an amount of flushing fluid applied per time remains constant.

5. The method as claimed in claim 1, wherein excess pressure of the flushing fluid measured at the nozzle is not less than 0.1 bar.

6. The method as claimed in claim 1, wherein the excess pressure of the flushing fluid measured at the nozzle is not more than 1.0 bar.

7. The method as claimed in claim 1, wherein the an amount of flushing fluid applied per time is not less than 0.01 l/min and not more than 1 l/min.

8. The method as claimed in claim 1, wherein the region is at a distance of not less than 2 mm, preferably 4 mm and not greater than 10 mm, preferable not greater than 6 mm from the center of the semiconductor wafer.

9. The method as claimed in claim 1, wherein the a surface area of the nozzle is not greater than 1.5 mm² and not less than 0.1 mm².

10. The method as claimed in claim 1, wherein the an amount of flushing fluid applied per time remains constant during the grinding.

11. The method as claimed in claim 1, wherein the region is at a distance of not less than 4 mm and not greater than 6 mm from the center of the semiconductor wafer.
